(19) United States
(12) Patent Application Publication
(10) Pub. No.: US 2024/0049402 A1
(43) Pub. Date: Feb. 8, 2024

(54) STRUCTURAL IMPROVEMENT FOR SOLID STATE DISCS

(71) Applicant: ABESTA INTERNATIONAL CO., LTD., New Taipei City (TW)

(72) Inventor: Ming-Shien Hsieh, New Taipei City (TW)

(21) Appl. No.: 17/878,928

(22) Filed: Aug. 2, 2022

(51) Int. Cl. H05K 5/00

(52) U.S. Cl. CPC H05K 5/0004

(57) ABSTRACT

The present invention discloses a structural improvement for solid state discs. The solid state disc comprises: a cover body, having a rectangular base board, three continuous sides of the periphery of the base board extending downward vertically to form three side boards, and the side without a side board forming an opening, the side boards on the two opposite long sides of the base board being formed with protruding and V-shaped clasps on the inner faces at positions close to the corners, said clasp forming a slope with the tip end of the V shape facing upward and the two legs straddled; and a base body, also having a rectangular bottom board, with three continuous sides of the periphery of the bottom board extending upward to form a plurality of side boards, and the side without a side board forming an opening. The base body can be covered by the cover body, and the side boards on the two opposite long sides of the bottom board are provided with long grooves at positions close to the corners. An electric circuit is fitted inside the above assembly structure to form a complete solid state disc. The structure of the present invention enables quicker assembly and disassembly and effectively enhances the efficiency.

### BACKGROUND OF INVENTION

### 1. Field of the Invention

The present invention relates generally to the improvement of the structure of a solid state disc, and more particularly to a structural improvement for solid state discs for quick assembly and disassembly without using any tool.

### 2. Description of Related Art

The existing computer storage devices such as hard discs are made up of matching shells and an electric circuit held inside. During the assembly, hand tools and screws are used to fix them together. Meanwhile, the internal electric circuit needs to be positioned and fixed through a plurality of screws to avoid displacement. Although this assembly method can obtain a good result, when the hard disk needs to be repaired, the disassembly is quite inconvenient because of the multiple screws used. To disassemble the hard disk, so many screws need to be removed. After the repair, they need to be fastened one by one. Such a method may cause poor locking of the screws and result in low assembly quality. There will be chances of looseness, shake or noise.

In order to improve the above-mentioned situation and provide a solution for the problems, a special structural form is designed for the assembly of the upper and lower covers as well as the electric circuit, so that the assembly of the solid state disc does not require any use of screws, and the internal electric circuit can be stably fixed between the upper and lower covers. The invention provides better appearance and more efficient assembly.

### SUMMARY OF THE INVENTION

The object of the present invention is to provide a structural improvement for solid state discs, so that the solid state discs can be assembled and disassembled quickly and conveniently, and meanwhile can have a neat and nice appearance.

In order to accomplish the above object, the inventor has designed a structural improvement for solid state discs. The improved structure of the solid state disc comprises: a cover body, having a rectangular base board, three continuous sides of the periphery of the base board extending downward vertically to form three side boards, and the side without a side board forming an opening, the side boards on the two opposite long sides of the base board being formed with protruding and V-shaped clasps on the inner faces at positions close to the corners, said clasp forming a slope with the tip end of the V shape facing upward and the two legs straddled; and a base body, also having a rectangular bottom board, and three continuous sides of the periphery of the bottom board extending upward to form a plurality of side boards, the side without a side board forming an opening. The base body can be covered by the cover body, and the side boards on the two opposite long sides of the bottom board are provided with long grooves at positions close to the corner, so that an electric circuit can be fitted inside to form a complete solid state disc.

In one embodiment, the side boards on the two opposite long sides of the base body further comprise a plurality of symmetric clamping portions bending horizontally inward, and a plurality of positioning columns provided on the bottom board at positions close to the corners.

### BRIEF DESCRIPTION OF THE DRAWINGS

FIG. 1 is an exploded view of the structure of a solid state disc according to a preferred embodiment of the invention;

FIG. 2 is another exploded view of the structure of a solid state disc according to a preferred embodiment of the invention;

FIG. 3 is an open-state view of the structure of a solid state disc according to a preferred embodiment of the invention;

FIG. 4 is an exploded lateral view of a solid state disc according to a preferred embodiment of the invention;

FIG. 5 is a combined lateral view (long side) of a solid state disc according to a preferred embodiment of the invention.

FIG. 6 is a combined lateral view (short side) of a solid state disc according to a preferred embodiment of the invention.

### DETAILED DESCRIPTION OF THE INVENTION

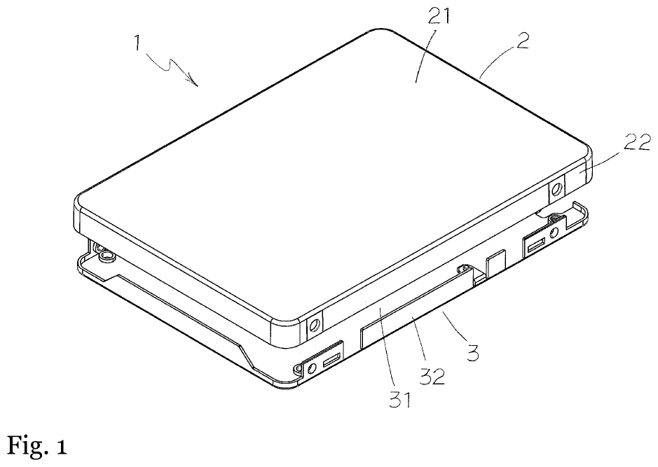

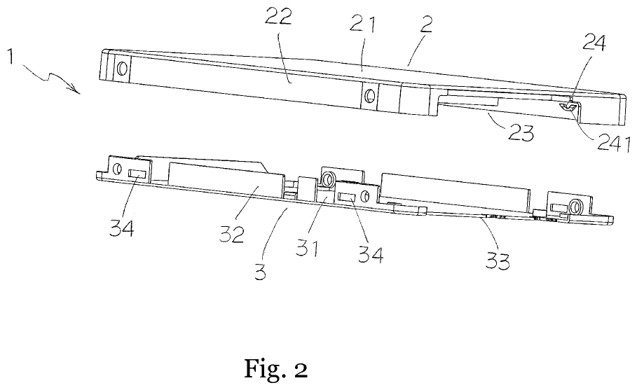

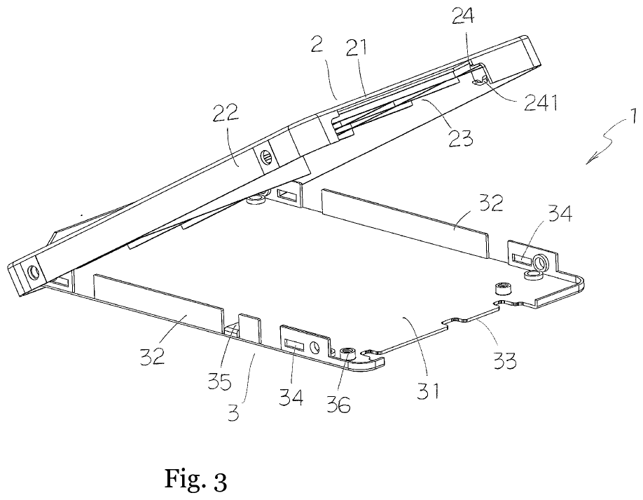

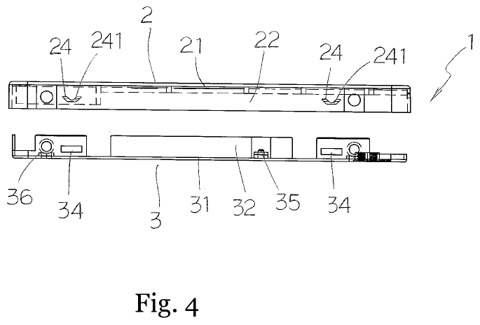

Referring to FIG. 1-FIG. 4, the present invention provides a structural improvement for solid state discs. The structure of the solid state disc (1) comprises: a cover body (2), a base body (3), and an electric circuit (not shown in the figures) fitted between the cover body (2) and the base body (3). The cover body (2) and the base body (3) can be assembled together. Their shapes are not limited. In the present embodiment, they are rectangular. Their sizes are not limited either, as long as the cover body (2) can perfectly cover the base body (3) and the two parts can be fixed together.

The cover body (2) has a rectangular base board (21). The three continuous sides of the periphery of the base board (21) extend downward vertically to form three side boards (22), and the side without a side board forming an opening (23). The side boards (22) on the two long sides of the base board (21) are formed with protruding and V-shaped clasps on the inner faces at positions close to the corners (24). The clasp (24) forms a slope (241) with the tip end of the V shape facing upward and the two legs straddled.

The base body (3) also has a rectangular bottom board (31). The three continuous sides of the periphery of the bottom board (31) extend upward vertically to form a plurality of side boards (32) and the side without a side board forms an opening (33). The size of the base body (3) is slightly smaller than the cover body (2), so that it can be fully covered by the cover body (2). The side boards (32) on the two long sides of the bottom board (31) are provided with long grooves (34) at positions close to the corners. The long grooves (34) and the clasp (24) match each other.

During assembly, the cover body (2) covers the base body (3) to form the assembly. Meanwhile, the clasps (24) on the side boards (21) on the two long sides of the cover body (2) will be inserted into the matching long grooves (34) on the side boards (31) on the two long sides of the base body (3), and be locked and fixed. In this way, the cover body (2) and the base body (3) can be assembled quickly.

Further, the side boards (32) on the two opposite long sides of the base body (3) comprise a plurality of symmetric clamping portions (35) bending horizontally inward, and the bottom board (31) is provided with a plurality of positioning columns (36) at positions close to the corners, so that an electric circuit can be fitted. This can realize the object and effect of quick assembly and fixation.

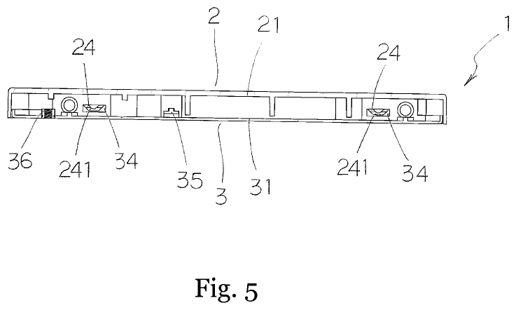

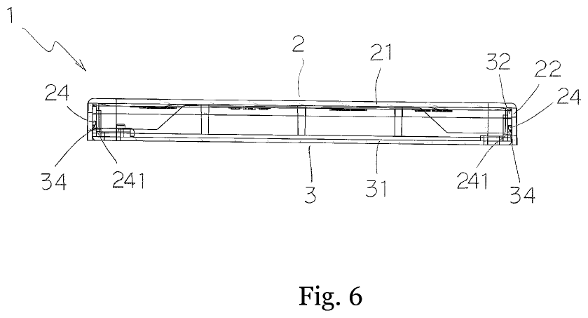

Referring to FIGS. 5-6, during actual assembly, the cover body (2) and the base body (3) are combined together, in a way that the cover body (2) covers the base body (3). Through the clasps (24) on the side boards (22, 32) and the matching long grooves (34) on the base body (3), the cover body (2) and the base body (3) can be quickly assembled without using any tool.

As described above, the clasps (24) and the long grooves (34) can be fixed together quickly and conveniently. The reasons are: the clasp (24) forms a slope (241) with the tip end of the V shape facing upward and the two legs straddled, when the side boards (22) of the cover body (2) overlap with the side boards of the base body (3), the slope (241) facilitates the sliding for subsequent locking. When the clasp (24) falls into the matching long groove (34), the straddled legs of the V shape of the clasp (24) on the above will be firmly locked inside the long groove (34), and thus the two parts are quickly assembled.

The structural improvement for solid state discs according to the invention facilitates quick assembly and disassembly of the cover body and the base body. On the other hand, the electric circuit fitted between the cover body and the base body can be firmly clamped and fixed. The invention can enhance the overall assembly efficiency and the entire solid state disc can be assembled without using any tool.

Although the invention has been explained in relation to its preferred embodiment, it is to be understood that many other possible modifications and variations can be made without departing from the spirit and scope of the invention as hereinafter claimed.

1. A structural improvement for solid state discs, comprising:
a cover body, having a rectangular base board, three continuous sides of the periphery of the base board extending downward vertically to form three side boards, and the side without a side board forming an opening, the side boards on the two opposite long sides of the base board being formed with protruding and V-shaped clasps on the inner faces at positions close to the corners, said clasp forming a slope with the tip end of the V shape facing upward and the two legs straddled; and
a base body, also having a rectangular bottom board, and three continuous sides of the periphery of the bottom board extending upward to form a plurality of side boards, the side without a side board forming an opening, the base body can be covered by the cover body, and the side boards on the two opposite long sides of the bottom board are provided with long grooves at positions close to the corner, so that an electric circuit can be fitted inside to form a complete solid state disc.

2. The structural improvement for solid state discs defined in claim 1, wherein the side boards on the two opposite long sides of the base body further comprise a plurality of symmetric clamping portions bending horizontally inward, and a plurality of positioning columns provided on the bottom board at positions close to the corners.
